(19) United States
(12) Patent Application Publication
(10) Pub. No.: US 2020/0348592 A1
(43) Pub. Date: Nov. 5, 2020

(54) RESIST UNDERLAYER COMPOSITIONS AND METHODS OF FORMING PATTERNS WITH SUCH COMPOSITIONS

(71) Applicant: ROHM AND HAAS ELECTRONIC MATERIALS LLC, Marlborough, MA (US)

(72) Inventors: Joshua Kaitz, Watertown, MA (US); Ke Yang, Natick, MA (US); Keren Zhang, Shrewsbury, MA (US); James F. Cameron, Brookline, MA (US); Li Cui, Westborough, MA (US); Emad Aqad, Northborough, MA (US); Shintaro Yamada, Shrewsbury, MA (US); Paul J. LaBeaume, Auburn, MA (US)

(21) Appl. No.: 16/530,273

(22) Filed: Aug. 2, 2019

Related U.S. Application Data
(63) Continuation-in-part of application No. 16/398,753, filed on Apr. 30, 2019, now abandoned.

(51) Int. Cl. G03F 7/075; G03F 7/09; C08L 25/18

(52) U.S. Cl. CPC G03F 7/0757; C08L 25/18; G03F 7/091

(57) ABSTRACT

A resist underlayer composition including a polyarylene ether, an additive polymer that is different from the polyarylene ether, and a solvent, wherein the additive polymer includes an aromatic or heteroaromatic group having at least one protected or free functional group selected from hydroxy, thiol, and amino.

### CROSS-REFERENCE TO RELATED APPLICATION

This application is a continuation-in-part of U.S. patent application Ser. No. 16/398,753 filed Apr. 30, 2019 in the United States Patent and Trademark Office, and all the benefits accruing therefrom under 35 U.S.C. § 119, the content of which is incorporated herein in its entirety by reference.

### FIELD

This present disclosure relates to spin-on carbon compositions used in the semiconductor industry as etch masks for lithography. Specifically, the disclosure relates to resist underlayer compositions with enhanced substrate adhesion.

### INTRODUCTION

Spin-on Carbon (SOC) compositions are used in the semiconductor industry as etch masks for lithography in advanced technology nodes for integrated circuit manufacturing. These compositions are often used in tri-layer and quad-layer photoresist integration schemes, where an organic or silicon containing anti-reflective coating and a patternable photoresist film layers are disposed on the bottom layer having a high carbon content SOC material.

An ideal SOC material should possess certain specific characteristics: it should be capable of being cast onto a substrate by a spin-coating process, should be thermally set upon heating with low out-gassing and sublimation, should be soluble in common solvents for good spin bowl compatibility, should have appropriate n/k to work in conjunction with the anti-reflective coating layer to impart low reflectivity necessary for photoresist imaging, and should have high thermal stability to avoid being damaged during later processing steps. In addition to these requirements, the ideal SOC material has to provide a planar film upon spin-coating and thermal curing over a substrate with topography and sufficient dry etch selectivity to silicon-containing layers located above and below the SOC films in order to transfer the photo-patterns into the final substrate in accurate manner.

Organic polyarylenes have been utilized to provide semiconductors with a low dielectric constant. The polyarylenes have also been used as an SOC material for patterning in tri-layer or quad-layer processes. Such polyarylene SOC formulations can have high thermal stability, high etch resistance, and good planarization under the test conditions. However, adhesion of the conventional polyarylene materials to inorganic substrates is limited, and may pose issues in some processing steps. For example, during substrate removal by wet chemical etch, conventional polyarylene formulations delaminate from the substrate, causing impermissible loss of pattern fidelity and substrate damage.

There remains a need for new SOC materials with improved adhesion properties.

### SUMMARY

Provided herein is a resist underlayer composition. The composition includes a polyarylene ether, an additive polymer that is different from the polyarylene ether, and a solvent. The additive polymer includes an aromatic or heteroaromatic group having at least one protected or free functional group selected from hydroxy, thiol, and amino.

Also provided herein is a method of forming a pattern. According to the method, a layer of the resist underlayer composition is applied over a substrate. The applied resist underlayer composition is subsequently cured to form a resist underlayer. A photoresist layer is then formed over the resist underlayer.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figure, to explain aspects of the present inventive concept. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “alkyl group” refers to a group derived from a straight or branched chain saturated aliphatic hydrocarbon having the specified number of carbon atoms and having a valence of at least one.

As used herein, the term “alkenyl group” refers to a group derived from a straight or branched chain unsaturated aliphatic hydrocarbon including at least one double bond, having the specified number of carbon atoms, and having a valence of at least one.

As used herein, the term “alkynyl group” refers to a group derived from a straight or branched chain unsaturated aliphatic hydrocarbon including at least one triple bond, having the specified number of carbon atoms, and having a valence of at least one.

As used herein, the term “cycloalkyl group” refers to a monovalent group having one or more saturated rings in which all ring members are carbon.

As used herein, the term “aryl”, which is used alone or in combination, refers to an aromatic hydrocarbon containing at least one ring and having the specified number of carbon atoms. The term “aryl” may be construed as including a group with an aromatic ring fused to at least one cycloalkyl ring.

As used herein, the term “formyl group” refers to a group having the formula —C(═O)H.

As used herein, the term “substituted” means including at least one substituent such as a halogen (F, Cl, Br, I), hydroxyl, amino, thiol, carboxyl, carboxylate, ester (including acrylates, methacrylates, and lactones), ketone, anhydride, amide, nitrile, sulfide, disulfide, sulfone, sulfoxide, sulfonamide, nitro, C₁₋₂₀ alkyl, C₁₋₂₀ cycloalkyl (including adamantyl), C₁₋₂₀ alkenyl (including norbornenyl), C₁₋₂₀ alkoxy, C₂₋₂₀ alkenoxy (including vinyl ether), C₆₋₃₀ aryl, C₆₋₃₀ aryloxy, C₇₋₃₀ alkylaryl, or C₇₋₃₀ alkylaryloxy.

When a group containing a specified number of carbon atoms is substituted with any of the groups listed in the preceding paragraphs, the number of carbon atoms in the resulting “substituted” group is defined as the sum of the carbon atoms contained in the original (unsubstituted) group and the carbon atoms (if any) contained in the substituent. For example, when the term “substituted C₁-C₂₀ alkyl” refers to a C₁-C₂₀ alkyl group substituted with C₆-C₃₀ aryl group, the total number of carbon atoms in the resulting aryl substituted alkyl group is C₇-C₅₀.

As used herein, the term “mixture” refers to any combination of the ingredients constituting the blend or mixture without regard to a physical form.

As noted above, known polyarylene SOC formulations can have high thermal stability, high etch resistance, and good planarization properties. However, adhesion of the conventional polyarylene materials to inorganic substrates may be limited, which may pose issues in subsequent processing steps. For example, during wet chemical etch, conventional polyarylene formulations delaminate from the substrate, causing impermissible loss of pattern fidelity and substrate damage.

The present inventors discovered that an addition of polar polymers including functional groups with strong substrate interactions substantially improves adhesion of the polyarylene material to the substrate. The novel resist underlayer compositions including a polyarylene ether and a polar additive polymer are described herein.

In an embodiment, a resist underlayer composition may include:
a polyarylene ether,
an additive polymer that is different from the polyarylene ether, and
a solvent.

The resist underlayer composition includes a polyarylene ether. As used herein, the term “polyarylene ether” refers to a compound having a substituted or unsubstituted aryleneoxy (—Ar—O—) structural unit, wherein “Ar” is a divalent group derived from an aromatic hydrocarbon. A “polyarylene ether” may refer to a poly(aryl ether), a poly(aryl ether ether ketone), a poly(aryl ether sulfone), or a poly(ether imide), poly(ether imidazole), and poly(ether benzoxazole). In all of these compounds, at least one substituted or unsubstituted structural unit (—Ar—O—) is present. A polyarylene ether, according to an embodiment, may include polymerized units of one or more first monomers having two or more cyclopentadienone moieties and one or more second monomers having an aromatic moiety and two or more alkynyl moieties. Some of the polyarylene ethers are commercially available. For example, a solution product of polyarylene ether under the tradename SiLK™ G can be obtained from The Dow Chemical Company. A polyarylene ether may be prepared by a Diels-Alder polymerization of a certain biscyclopentadienone monomer and a certain polyethynyl-substituted aromatic compound in a molar ratio of 1:<1 or 1:>1, and may have a M_{w} of approximately 3,000-5,000 Daltons (Da) and a PDI of approximately 1.3. In an embodiment, the biscyclopentadienone monomer and the polyethynyl-substituted aromatic compound may be in a molar ratio of 1:1.25.

To increase polymer solubility, one or more first monomers and/or the one or more second monomers may be substituted with polar moieties, such as those solubility enhancing moieties disclosed in U.S. Published Pat. App. No. 2017/0009006 (which is incorporated herein in its entirety by reference). Suitable solubility enhancing polar moieties include, without limitation: hydroxyl, carboxyl, thiol, nitro, amino, amido, sulfonyl, sulfonamide moieties, ester moieties, quaternary amino moieties, and the like. Exemplary first monomers having one or more solubility enhancing polar moieties are disclosed in U.S. patent application Ser. No. 15/790,606, filed on Oct. 27, 2017 (which is incorporated herein in its entirety by reference). Exemplary second monomers having one or more solubility enhancing polar moieties are those disclosed in U.S. Published Pat. App. No. 2017/0009006 (which is incorporated herein in its entirety by reference). Preferably, the one or more first monomers are free of solubility enhancing polar moieties. Preferably, the one or more second monomers are free of solubility enhancing polar moieties. More preferably, both the more first monomers and second monomers are free of solubility enhancing polar moieties.

Any compound containing two or more cyclopentadienone moieties capable of undergoing a Diels-Alder reaction may suitably be used as the first monomer to prepare the present polyarylene ethers. Alternatively, a mixture of two or more different first monomers, each having two or more cyclopentadienone moieties, may be used as the first monomer. Preferably, only one first monomer is used. Preferably, the first monomer has two to four cyclopentadienone moieties, and more preferably two cyclopentadienone moieties (also referred to herein as biscyclopentadienones). Suitable first monomers having two or more cyclopentadienone moieties are well-known in the art, such as those described in U.S. Pat. Nos. 5,965,679; 6,288,188; and 6,646,081; and in Int. Pat. Pubs. WO 97/10193, WO 2004/073824 and WO 2005/030848 (all of which are incorporated herein in their entireties by reference).

It is preferred that the first monomer has the structure shown in Formula (1)

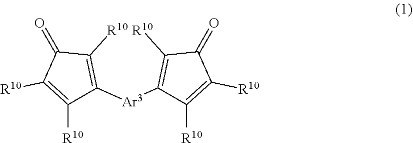

wherein each R¹⁰ is independently chosen from H, C₁₋₆-alkyl, and optionally substituted C₅₋₂₀-aryl; and Ar³ is an aryl moiety having from 5 to 60 carbons. In Formula (1), “substituted C₅₋₂₀-aryl” refers to a C₅₋₂₀-aryl having one or more of its hydrogens replaced with one or more of halogen, C₁₋₁₀-alkyl, C₅₋₁₀-aryl, —C≡C—C₅₋₁₀-aryl, or a heteroatom-containing radical having from 0 to 20 carbon atoms and one or more heteroatoms chosen from O, S and N, preferably from halogen, C₁₋₁₀-alkyl, C₆₋₁₀-aryl, and —C≡C—C₆₋₁₀-aryl, and more preferably from phenyl and —C≡C-phenyl. As used herein, “substituted phenyl” refers to a phenyl moiety substituted with one or more of halogen, C₁₋₁₀-alkyl, C₅₋₁₀-aryl, —C≡C—C₅₋₁₀-aryl, or a heteroatom-containing radical having from 0 to 20 carbon atoms and one or more heteroatoms chosen from O, S and N, and preferably with one or more of halogen, C₁₋₁₀-alkyl, C₆₋₁₀-aryl, and —C≡C—C₆₋₁₀-aryl, and more preferably from phenyl and —C≡C-phenyl. Exemplary heteroatom-containing radicals having from 0 to 20 carbon atoms and one or more heteroatoms chosen from O, S and N include, without limitation, hydroxy, carboxy, amino, C₁₋₂₀-amido, C₁₋₁₀-alkoxy, C₁₋₂₀-hydroxyalkyl, C₁₋₃₀-hydroxy(alkyleneoxy), and the like. Preferably, each R¹⁰ is independently chosen from C₁₋₆-alkyl, phenyl and substituted phenyl, more preferably each R¹⁰ is phenyl or substituted phenyl, and yet more preferably phenyl or —C₆H₄—C≡C-phenyl. A wide variety of aromatic moieties are suitable for use as Ar³, such as those disclosed in U.S. Pat. No. 5,965,679 (which is incorporated herein in its entirety by reference). Preferably, Ar³ has from 5 to 40 carbons, and more preferably from 6 to 30 carbons. Preferred aryl moieties useful for Ar³ include pyridyl, phenyl, naphthyl, anthracenyl, phenanthryl, pyrenyl, coronenyl, tetracenyl, pentacenyl, tetraphenyl, benzotetracenyl, triphenylenyl, perylenyl, biphenyl, binaphthyl, diphenyl ether, dinaphthyl ether, and those having the structure shown in Formula (2)

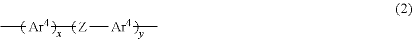

wherein x is an integer chosen from 1, 2 or 3; y is an integer chosen from 0, 1, or 2; each Ar⁴ is independently chosen from

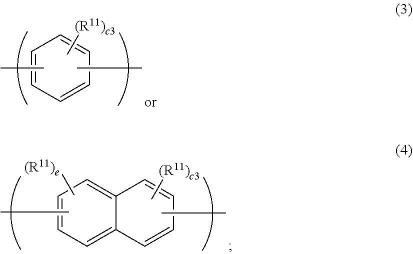

each R¹¹ is independently chosen from halogen, C₁₋₆-alkyl, C₁₋₆-haloalkyl, C₁₋₆-alkoxy, C₁₋₆-haloalkoxy, phenyl, and phenoxy; c3 is an integer from 0 to 4; each of d3 and e is an integer from 0 to 3; each Z is independently chosen from a single covalent chemical bond, O, S, NR¹², PR¹², P(═O)R¹², C(═O), C(R¹³)(R¹⁴) and Si(R¹³)(R¹⁴); R¹², R¹³ and R¹⁴ are independently chosen from H, C₁₋₄-haloalkyl, and phenyl. It is preferred that x is 1 or 2, and more preferably 1. It is preferred that y is 0 or 1, and more preferably 1. Preferably, each R¹¹ is independently chosen from halogen, C₁₋₄-alkyl, C₁₋₄-haloalkyl, C₁₋₄-alkoxy, C₁₋₄-haloalkoxy, and phenyl, and more preferably from fluoro, C₁₋₄-alkyl, C₁₋₄-fluoroalkyl, C₁₋₄-alkoxy, C₁₋₄-fluoroalkoxy, and phenyl. It is preferred that c3 is from 0 to 3, more preferably from 0 to 2, and yet more preferably 0 or 1. It is preferred that each of d3 and e is independently 0 to 2, and more preferably 0 or 1. In Formula (4), it is preferred that d3+e=0 to 4, and more preferably 0 to 2. Each Z is preferably independently chosen from 0, S, NR¹², C(═O), C(R¹³)(R¹⁴), and Si(R¹³)(R¹⁴), more preferably from 0, S, C(═O), and C(R¹³)(R₁₄), and yet more preferably from 0, C(═O), and C(R¹³)(R¹⁴). It is preferred that each R¹², R¹³, and R¹⁴ are independently chosen from H, C₁₋₄-alkyl, C₁₋₄-fluoroalkyl, and phenyl; and more preferably from H, C₁₋₂-fluoroalkyl, and phenyl. Preferably, the aryl moiety of Ar³ has at least one ether linkage, more preferably at least one aromatic ether linkage, and even more preferably one aromatic ether linkage. It is preferred that Ar³ has the structure of Formula (2). Preferably, each Ar⁴ has the Formula (3), and more preferably each Ar⁴ has the Formula 3 and Z is 0.

Any compound having an aryl moiety and two or more alkynyl groups capable of undergoing a Diels-Alder reaction may suitably be used as the second monomer to prepare the present polymers. Preferably, the second monomer has an aryl moiety substituted with two or more alkynyl groups. It is preferred that a compound having an aryl moiety substituted with two to four, and more preferably two or three, alkynyl moieties is used as the second monomer. Preferably, the second monomers have an aryl moiety substituted with two or three alkynyl groups capable of undergoing a Diels-Alder reaction. Suitable second monomers are those of Formula (5)

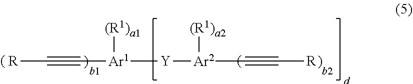

wherein each Ar¹ and Ar² is independently a C₅₋₃₀-aryl moiety; each R is independently chosen from H, and optionally substituted C₅₋₃₀-aryl; each R¹ is independently chosen from —OH, —CO₂H, G₁₋₁₀-alkyl, C₁₋₁₀-hydroxyalkyl, C₁₋₁₀-hydroxyalkyl, C₁₋₁₀-carboxyalkyl, G₁₋₁₀-alkoxy, CN, and halo; each Y is independently a single covalent chemical bond or a divalent linking group chosen from —O—, —S—, —S(═O)—, —S(═O)₂—, —C(═O)—, —(C(R⁹)₂)^{z}—, C₆₋₃₀-aryl, and —(C(R⁹)₂)_{z}—(C₆₋₃₀-aryl)-(C(R⁹)₂)_{z2}—; each R⁹ is independently chosen from H, hydroxy, halo, C₁₋₁₀-alkyl, C₁₋₁₀haloalkyl, and C₆₋₃₀-aryl; a1=0 to 4; each a2=0 to 4; b1=1 to 4; each b2=0 to 2; a1+each a2=0 to 6; b1+each b2=2 to 6; d=0 to 2; z=1 to 10; z1=0 to 10; z2=0 to 10; and z1+z2=1 to 10. Each R is preferably independently chosen from H and C₆₋₂₀-aryl, more preferably from H and C₆₋₁₀ aryl, and yet more preferably from H and phenyl. It is preferred that each R is independently chosen from C₁₋₁₀-alkyl, C₁₋₁₀-haloalkyl, C₁₋₁₀-hydroxyalkyl, C₁₋₁₀-alkoxy, and halo, and more preferably from C₁₋₁₀-alkyl, C₁₋₁₀-haloalkyl, and halo. Preferably, each Y is independently a single covalent chemical bond or a divalent linking group chosen from —O—, —S—, —S(═O)—, —S(═O)₂—, —C(═O)—, —(C(R⁹)₂)_{z}—, and C₆₋₃₀-aryl, and more preferably a single covalent chemical bond, —O—, —S—, —S(═O)₂—, —C(═O)—, and —(C(R⁹)₂)_{z}—. Each R⁹ is preferably independently H, halo, C₁₋₁₀alkyl, C₁₋₁₀haloalkyl, or C₆₋₃₀-aryl, and more preferably fluoro, C₁₋₆alkyl, C₁₋₆-fluoroalkyl, or C₆₋₂₀-aryl. Preferably, a1=0 to 3, and more preferably 0 to 2. It is preferred that each a2=0 to 2. Preferably, a1+a2=0 to 4, more preferably 0 to 3, and yet more preferably 0 to 2. It is preferred that b1=1 to 3, and more preferably 1 or 2. It is preferred that each b2=0 to 2; and more preferably 0 or 1. Preferably, b1+each b2=2 to 4, and more preferably 2 or 3. It is preferred that d=0 or 1, and more preferably 0. Preferably, z=1 to 6, more preferably 1 to 3, and even more preferably z=1. Preferably, z1 and z2 are each 0 to 5. It is preferred that z1+z2=1 to 6, and more preferably 2 to 6.

Suitable aryl moieties for Ar¹ and Ar² include, but are not limited to, pyridyl, phenyl, naphthyl, anthracenyl, phenanthryl, pyrenyl, coronenyl, tetracenyl, pentacenyl, tetraphenyl, benzotetracenyl, triphenylenyl, perylenyl, biphenyl, binaphthyl, diphenyl ether, dinaphthyl ether, carbazole, and fluorenyl. It is preferred that Ar¹ and each Ar² in Formula (5) are independently a C₆₋₂₀ aryl moiety. Preferred aryl moieties for Ar and each Ar² are phenyl, naphthyl, anthracenyl, phenanthryl, pyrenyl, tetracenyl, pentacenyl, tetraphenyl, triphenylenyl, and perylenyl.

Preferred second monomers of Formula (5) are those of Formulas (6) and (7):

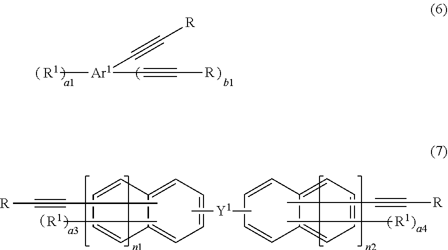

wherein Ar¹, R, R¹, a1 and b1 are as defined above for Formula (5); a3 is 0 or 2; a4 is 0 to 2; each of n1 and n2 is independently 0 to 4; and Y is a single covalent chemical bond, O, S, S(═O)₂, C(═O), C(CH₃)₂, CF₂, and C(CF₃)₂. It will be appreciated by those skilled in the art that the brackets (“[ ]”) in Formula (7) refer to the number of aromatic rings fused to the phenyl ring. Accordingly, when n1 (or n2)=0, the aromatic moiety is phenyl; when n1 (or n2)=1, the aromatic moiety is naphthyl; when n1 (or n2)=2, the aromatic moiety may be anthracenyl or phenanthryl; when n1 (or n2)=3, the aromatic moiety may be tretacenyl, tetraphenyl, triphenylenyl, or pyrenyl; and when n1 (or n2)=4, the aromatic moiety may be perylenyl or benzotetracenyl. In Formula (6), a1 is preferably 0 to 2, and more preferably 0. It is preferred that b1 in Formula (6) is 1 or 2. R is preferably H or phenyl. Each R in each of Formulas (6) and (7) is preferably independently chosen from C₁₋₁₀alkyl, C₁₋₁₀-haloalkyl, C₁₋₁₀-hydroxyalkyl, C₁₋₁₀-alkoxy, and halo, and more preferably from C₁₋₁₀-alkyl, C₁₋₁₀-haloalkyl, and halo. Ar¹ in Formula (6) is preferably phenyl, naphthyl, anthracenyl, pyrenyl, and perylenyl, more preferably phenyl, naphthyl and pyrenyl, and even more preferably phenyl. In Formula (7), it is preferred that n1 and n2 are independently chosen from 0, 1, 3, and 4, more preferably from 0, 1 and 3, and even more preferably from 1 and 3. It is further preferred that n=n2. In Formula (7), Y is preferably a single covalent chemical bond, O, S(═O)₂, C(═O), C(CH₃)₂, CF₂, or C(CF₃)₂, and more preferably a single covalent chemical bond.

Particularly preferred monomers of Formula (6) are monomers of Formulas (8) to (12):

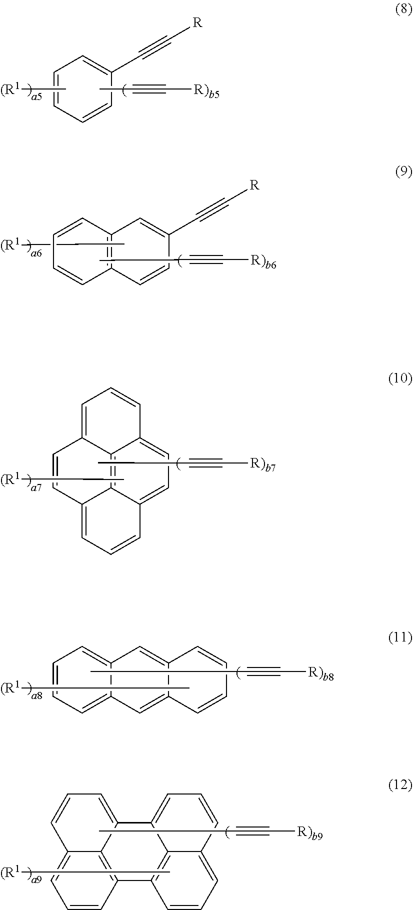

wherein R and R¹ are as described above for Formula (6); a5=0 to 2; each of a6, a7, a8 and a9 are independently 0 to 4; b5 and b6 are each chosen from 1 to 3; and b7, b8, and b9 are each chosen from 2 to 4. Preferably, a5=0 or 1, and more preferably 0. It is preferred that a6 is 0 to 3, more preferably 0 to 2, and even more preferably 0. Preferably, each of a7 to a9 is independently 0 to 3, and more preferably 0 to 2. It is preferred that b5 and b6 are each chosen from 1 and 2. Preferably, b7, b8, and b9 are each 2 or 3. Compound (8) is more particularly preferred. Preferably, in compound (8), each R is independently H or phenyl, and more preferably each R is H or phenyl. More preferably, each R¹ in Formulas (8) to (12) is independently chosen from C₁₋₁₀-alkyl, C₁₋₁₀-haloalkyl, C₁₋₁₀-hydroxyalkyl, C₁₋₁₀-alkoxy, and halo, and more preferably from C₁₋₁₀-alkyl, C₁₋₁₀-haloalkyl, and halo.

In the monomers of Formulas (5) to (12), any two alkynyl moieties may have an ortho-, meta- or para-relationship to each other, and preferably a meta- or para-relationship to each other. Preferably, the alkynyl moieties in the monomers of Formulas (5) to (12) do not have an ortho-relationship to each other. Suitable monomers of Formulas (5) to (12) are generally commercially available or may be readily prepared by methods known in the art.

Exemplary second monomers include, without limitation: 1,3-diethynylbenzene; 1,4-diethynylbenzene; 4,4′-diethynyl-1,1′-biphenyl; 3,5-diethynyl-1,1′-biphenyl; 1,3,5-triethynylbenzene; 1,3-diethynyl-5-(phenylethynyl)benzene; 1,3-bis(phenylethynyl)benzene; 1,4-bis(phenylethynyl)-benzene; 1,3,5-tris(phenylethynyl)benzene; 4,4′-bis(phenylethynyl)-1,1′-biphenyl; 4,4′-diethynyl-diphenylether; and mixtures thereof. More preferably, the monomers of Formula (5) are chosen from: 1,3-diethynylbenzene; 1,4-diethynylbenzene; 1,3,5-triethynylbenzene; 1,3,5-tris-(phenylethynyl)benzene; 4,4′-diethynyl-1,1′-biphenyl; 1,3-bis(phenylethynyl)-benzene; 1,4-bis(phenylethynyl)benzene; 4,4′-bis(phenylethynyl)-1,1′-biphenyl; and mixtures thereof. Even more preferably, the second monomers are chosen from: 1,3-diethynylbenzene; 1,4-diethynylbenzene; 4,4′-diethynyl-1,1′-biphenyl; 1,3,5-triethynylbenzene; 1,3,5-tris(phenylethynyl)benzene; and mixtures thereof.

Polyarylene ethers, according to an embodiment, may be formed of one or more first monomers of Formula (1), or a mixture of two or more different first monomers of Formula (1). The present polyarylene ethers may be formed of one second monomer of Formula (5), or a mixture of two or more different second monomers of Formula (5). Monomers of Formula (6) are preferred second monomers. It is preferred that the present polyarylene ethers are formed of polymerized units of one or more first monomers of Formula (1) and one or more second monomers of Formula (6). In an alternate preferred embodiment, the present polyarylene ethers are formed of polymerized units of one or more first monomers of Formula (1) and one or more second monomers of Formula (7), or in yet another alternate embodiment of one or more first monomers of Formula (1), one or more second monomers of Formula (6) and one or more second monomers of Formula (7). Mixtures of polyarylene ethers including as polymerized units one or more first monomers of Formula (1) and one or more second monomers of Formula (5) may suitably be used.

The present polyarylene ethers may optionally further include as polymerized units one or more end-capping monomers. Preferably, only one end-capping monomer is used. As used herein, the term “end-capping monomer” refers to monomers having a single dienophilic moiety, where such dienophilic moiety functions to cap one or more ends of the present polymers such that capped ends of the polymers are incapable of further Diels-Alder polymerization. Preferably, the dienophilic moiety is an alkynyl moiety. Optionally, the end-capping monomer may include one or more solubility enhancing polar moieties, such as those disclosed in U.S. Published Pat. App. No. 2016/0060393 (which is incorporated herein in its entirety by reference). It is preferred that the end-capping monomers are free of solubility enhancing polar moieties. Preferred end-capping monomers are those of Formula (13)

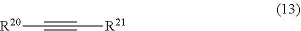

wherein R²⁰ and R²¹ are each independently chosen from H, C₅₋₂₀-aryl, and C₁₋₂₀-alkyl. Preferably, R² and R²¹ are each independently chosen from H, C₆₋₂₀-aryl, and C₁₋₂₀-alkyl. More preferably, R²⁰ is C₅₋₂₀-aryl, and even more preferably C₆₋₂₀-aryl. R²¹ is preferably H or C₁₋₂₀-alkyl. When employed, such end-capping monomers are typically used in a molar ratio of 1:0.01 to 1:1.2 of first monomer to end-capping monomer.

Exemplary end capping monomers include, but are not limited to: styrene; α-methylstyrene; β-methylstyrene; norbornadiene; ethynylpyridine; ethynylbenzene; ethynylnaphthylene; ethynylpyrrene; ethynylanthracene; ethynylphenanthrene; diphenylacetylene; 4-ethynyl-1,1′-biphenyl; 1-propynylbenzene; propiolic acid; 1,4-butynediol; acetylenedicarboxylic acid; ethynylphenol; 1,3-diethynylbenzene; propargyl aryl esters; ethynyl phthalic anhydride; diethynyl benzoic acid; and 2,4,6-tris(phenylethynyl)anisole. Preferred end capping monomers are: ethynylbenzene, norbornadiene; ethynylnaphthylene, ethynylpyrrene, ethynylanthracene, ethynylphenanthrene, and 4-ethynyl-1,1′-biphenyl.

The following are examples of the polyarylene ethers:

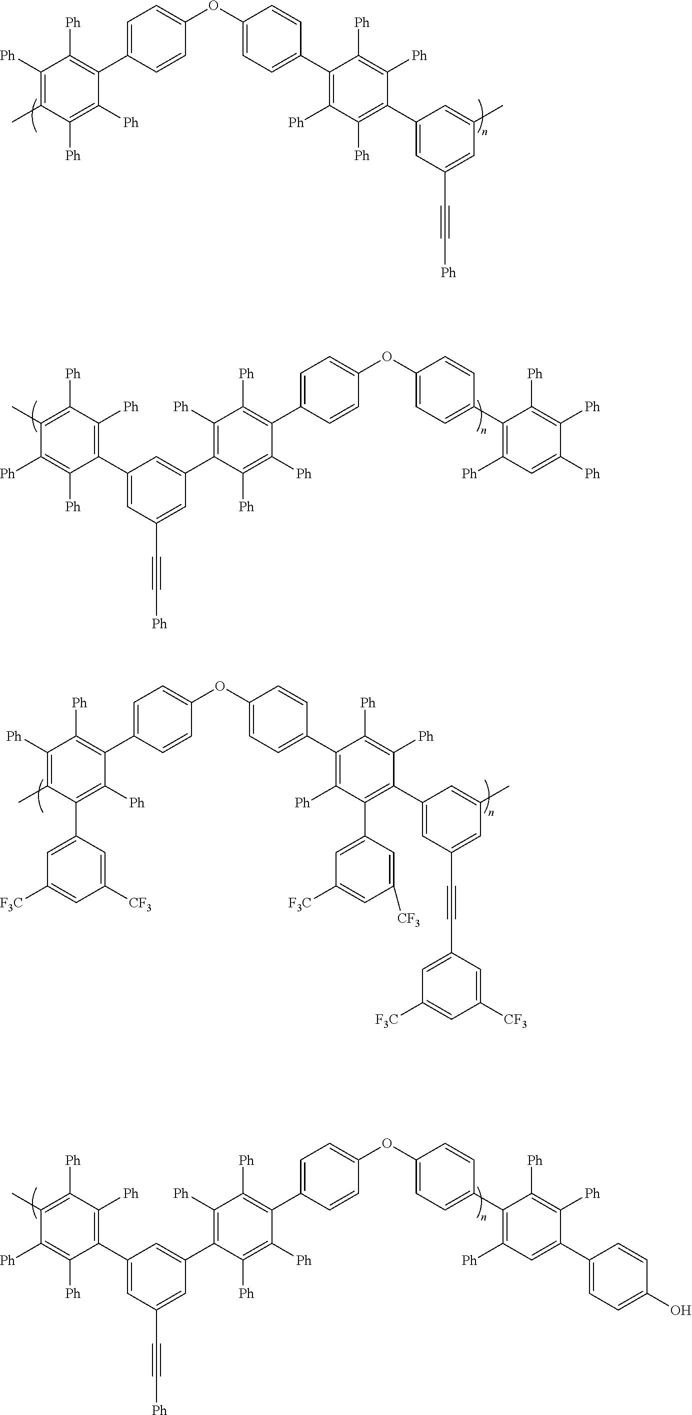

The polyarylene ethers, according to an embodiment, are prepared by reacting one or more first monomers with one or more second monomers and any optional end capping monomers in a suitable organic solvent. The mole ratio of the total first monomers to the total second monomers is from 1:>1, preferably from 1:1.01 to 1:1.5, more preferably from 1:1.05 to 1:1.4, and yet more preferably from 1:1.2 to 1:1.3. The total moles of second monomers used are greater than the total moles of first monomers used. Suitable organic solvents useful to prepare the present polymers are benzyl esters of (C₂-C₆)alkanecarboxylic acids, dibenzyl esters of (C₂-C₆)alkanedicarboxylic acids, tetrahydrofurfuryl esters of (C₂-C₆)alkanecarboxylic acids, ditetrahydrofurfuryl esters of (C₂-C₆)alkanedicarboxylic acids, phenethyl esters of (C₂-C₆)alkanecarboxylic acids, diphenethyl esters of (C₂-C₆)alkanedicarboxylic acids, aromatic ethers, N-methyl pyrrolidone (NMP), and gamma-butyrolactone (GBL). Preferred aromatic ethers are diphenyl ether, dibenzyl ether, (C₁-C₆)alkoxy-substituted benzenes, benzyl (C₁-C₆)alkyl ethers, NMP and GBL, and more preferably (C₁-C₄)alkoxy-substituted benzenes, benzyl (C₁-C₄)alkyl ethers, NMP, and GBL. Preferred organic solvents are benzyl esters of (C₂-C₄)alkanecarboxylic acids, dibenzyl esters of (C₂-C₄)alkanedicarboxylic acids, tetrahydrofurfuryl esters of (C₂-C₄)alkanecarboxylic acids, ditetrahydrofurfuryl esters of (C₂-C₄)alkanedicarboxylic acids, phenethyl esters of (C₂-C₄)alkanecarboxylic acids, diphenethyl esters of (C₂-C₄)alkanedicarboxylic acids, (C₁-C₆)alkoxy-substituted benzenes, benzyl (C₁-C₆)alkyl ethers, NMP, and GBL, more preferably benzyl esters of (C₂-C₆)alkanecarboxylic acids, tetrahydrofurfuryl esters of (C₂-C₆)alkanecarboxylic acids, phenethyl esters of (C₂-C₆)alkanecarboxylic acids, (C₁-C₄)alkoxy-substituted benzenes, benzyl (C₁-C₄)alkyl ethers, dibenzyl ether, NMP, and GBL, and yet more preferably benzyl esters of (C₂-C₆)alkanecarboxylic acids, tetrahydrofurfuryl esters of (C₂-C₆)alkanecarboxylic acids, (C₁-C₄)alkoxy-substituted benzenes, benzyl (C₁-C₄)alkyl ethers, NMP, and GBL. Exemplary organic solvents include, without limitation, benzyl acetate, benzyl proprionate, tetrahydrofurfuryl acetate, tetrahydrofurfuryl propionate, tetrahydrofurfuryl butyrate, anisole, methylanisole, dimethylanisole, dimethoxybenzene, ethylanisole, ethoxybenzene, benzyl methyl ether, and benzyl ethyl ether, and preferably benzyl acetate, benzyl proprionate, tetrahydrofurfuryl acetate, tetrahydrofurfuryl propionate, tetrahydrofurfuryl butyrate, anisole, methylanisole, dimethylanisole, dimethoxybenzene, ethylanisole, and ethoxybenzene.

The polyarylene ethers, according to an embodiment, may be prepared by combining the first monomer, the second monomer, any optional end capping monomer, and organic solvent, each as described above, in any order in a vessel and heating the mixture. Preferably, the present polymers are prepared by combining the first monomer, the second monomer, and organic solvent, each as described above, in any order in a vessel and heating the mixture. Alternatively, the first monomer may first be combined with the organic solvent in a vessel, and the second monomer then added to the mixture. In one alternate embodiment, the first monomer and organic solvent mixture is first heated to the desired reaction temperature before the second monomer is added. The second monomer may be added at one time, or alternatively, may be added over a period of time, such as from 0.25 to 6 hours, to reduce exotherm formation. The first monomer and organic solvent mixture may first be heated to the desired reaction temperature before the second monomer is added. The present end-capped polyarylene ethers may be prepared by first preparing a polyarylene ether by combining the first monomer, the second monomer, and organic solvent in any order in a vessel and heating the mixture, followed by isolating the polyarylene ether, and then combining the isolated polyarylene ether with an end-capping monomer in an organic solvent and heating the mixture for a period of time. Alternatively, the present end-capped polyarylene ethers may be prepared by combining the first monomer, the second monomer, and organic solvent in any order in a vessel and heating the mixture for a period of time to provide the desired polyarylene ether, and then adding the end-capping monomer to the reaction mixture containing the polyarylene ether and heating the reaction mixture for a period of time. The reaction mixture is heated at a temperature of 100 to 250° C. Preferably, the mixture is heated to a temperature of 150 to 225° C., and more preferably to a temperature of 175 to 215° C. Typically, the reaction is allowed to proceed for 2 to 20 hours, preferably 2 to 8 hours, and more preferably 2 to 6 hours, with shorter reaction times yielding relatively lower molecular weight polyarylene ethers. The reaction may be carried out under oxygen-containing atmosphere, but an inert atmosphere such as nitrogen is preferred. Following the reaction, the resulting polyarylene ethers may be isolated from the reaction mixture or used as is for coating a substrate.

While not intending to be bound by theory, it is believed that the present polyarylene ethers are formed through the Diels-Alder reaction of the cyclopentadienone moieties of the first monomer with the alkynyl moieties of the second monomer upon heating. During such Diels-Alder reaction, a carbonyl-bridged species forms. It will be appreciated by those skilled in the art that such carbonyl-bridged species may be present in the polymers. Upon further heating, the carbonyl bridging species will be essentially fully converted to an aromatic ring system. Due to the mole ratio of the monomers used, the present polymers contain arylene rings in the polyarylene ether backbone as illustrated in the following reaction scheme, where A is the first monomer, B is the second monomer, and Ph is phenyl.

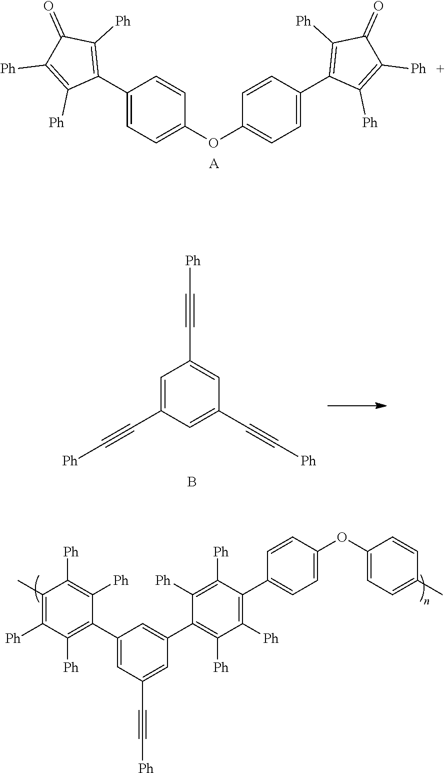

The polyarylene ethers, according to an embodiment, have a weight average molecular weight (M_{W}) of 1,000 to 6,000 Da, preferably from 1,000 to 5,000 Da, more preferably from 2,000 to 5,000 Da, yet more preferably from 2,500 to 5,000 Da, even more preferably from 2,700 to 5,000 Da, and still more preferably from 3,000 to 5,000 Da. Polyarylene ethers, according to an embodiment, typically have a number average molecular weight (Mₙ) in the range of 1,500 to 3,000 Da. The present polyarylene ethers have a polydispersity index (PDI) of 1 to 2, preferably from 1 to 1.99, more preferably from 1 to 1.9, yet more preferably from 1 to 1.8, and still more preferably from 1.25 to 1.75. PDI=M_{W}/Mₙ. The Mₙ and M_{W} of the present polymers are determined by the conventional technique of gel permeation chromatography (GPC) against polystyrene standards using uninhibited tetrahydrofuran (THF) as eluting solvent at 1 mL/min and a differential refractometer detector. The present polyarylene ethers have a degree of polymerization (DP) in the range of from 2 to 5, preferably from 2 to 4.5, more preferably from 2 to 3.75, and yet more preferably from 2 to 3.5. DP is calculated by dividing the molecular weight of the polymer by the molecular weight of the respective repeating unit, exclusive of any end capping monomer present. The present polyarylene ethers have a total first monomer to total second monomer mole ratio of 1 to ≥1, preferably a ratio of 1:1.01 to 1:1.5, more preferably a ratio of 1:1.05 to 1:1.4, yet more preferably a ratio of 1:1.1 to 1:1.3, still more preferably from 1:1.15 to 1:1.3, and even more preferably from 1:1.2 to 1:1.3. The ratio of the total moles of first monomer to total moles of second monomer are typically calculated as the feed ratio of the monomers, but may also be determined using conventional matrix-assisted laser desorption/ionization (MALDI) time-of-flight (TOF) mass spectrometry, with silver trifluoroacetate being added to the samples to facilitate ionization. A suitable instrument is a Bruker Daltonics Ultraflex MALDI-TOF mas spectrometer equipped with a nitrogen laser (337 nm wavelength). Particularly preferred polymers, according to an embodiment, are those having a M_{W} of 3,000 to 5,000, a PDI of 1.25 to 1.75, and a ratio of total moles of first monomer to total moles of second monomer of from 1:1.2 to 1:1.3.

The composition may further include an additive polymer, which is different from the polyarylene ether. To increase adhesion to the substrate, the additive polymer includes at least one protected or free polar functional group. As used herein, the term “polar functional group” refers to a functional group including at least one heteroatom. The additive polymer may include an aromatic or heteroaromatic group having at least one protected or free functional group selected from hydroxy, thiol, and amino. The term “free functional group” as used herein refers to a non-protected functional group. Thus, the term “free hydroxy group” refers to “—OH,” the term “free thiol group” refers to “—SH,” and the term “free amino group” refers to “—NH₂.” The term “protected functional group” as used herein refers to a functional group capped with a protecting group which reduces or eliminates reactivity of the free functional group. The protecting group may optionally include —O—, —NR— (wherein R is hydrogen or C₁₋₁₀ alkyl group), —C(═O)—, or a combination thereof.

The protecting group may include a formyl group, a substituted or unsubstituted linear or branched C₁₋₁₀ alkyl group, a substituted or unsubstituted C₃₋₁₀ cycloalkyl group, a substituted or unsubstituted C₂₋₁₀ alkenyl group, a substituted or unsubstituted C₂₋₁₀ alkynyl group, or a combination thereof. The protecting group may include —O—, —NR— (wherein R is hydrogen or C₁₋₁₀ alkyl group), —C(═O)—, or a combination thereof, at any portion of the protecting group.

In an embodiment, the functional group may be hydroxyl, which may be protected as an alkyl ether to form a structure OR, wherein R is a C₁₋₁₀ linear or branched alkyl group. Preferred alkyl groups include methyl, ethyl, n-propyl, iso-propyl, n-butyl, iso-butyl, and tert-butyl groups.

In another embodiment, the protecting group may be a formyl group [—C(═O)H] or a C₂₋₁₀ alkanoyl group [—C(═O)R, wherein R is a C₁₋₁₀ linear or branched alkyl group]. Preferably, the C₂₋₁₀ alkanoyl group is an acetyl group [—C(═O)CH₃] or a propionyl group [—C(═O)CH₂CH₃]. The functional group may be a hydroxy group protected with an acetyl group or a propionyl group to form an ester —OC(═O)CH₃ or —OC(═O)CH₂CH₃, respectively.

In another embodiment, the hydroxyl group may be protected as a carbonate to form a structure —OC(═O)OR, wherein R is a C₁₋₁₀ linear or branched alkyl group. Preferred carbonate groups include —OC(═O)OCH₃, —OC(═O)OCH₂CH₃, —OC(═O)OCH₂CH₂CH₃, —OC(═O)OCH(CH₃)₂, or —OC(═O)OC(CH₃)₃.

In another embodiment, the hydroxyl group may be protected as a carbamate to form a structure —OC(═O)NRR′, wherein R and R′ are each independently a C₁₋₁₀ linear or branched alkyl group. Preferred carbamate groups include —OC(═O)NHCH₃, —OC(═O)NHCH₂CH₃, —OC(═O)NHCH₂CH₂CH₃, —OC(═O)NHCH(CH₃)₂, —OC(═O)NHC(CH₃)₃, or —OC(═O)NH(CH₃)₂.

In an embodiment, the protecting group may be a polymerizable group which includes a substituted or unsubstituted C₂₋₁₀ alkenyl group, a substituted or unsubstituted C₂₋₁₀ alkynyl group, or a combination thereof.

The additive polymer may include a structural unit represented by Formula (I):

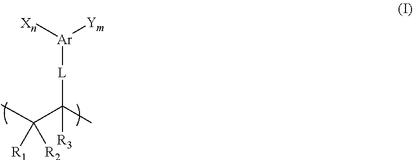

In Formula (I), Ar may be a C₆₋₄₀ aromatic organic group or a C₃₋₄₀ heteroaromatic organic group, each of which may be a single aromatic or heteroaromatic group or a fused aromatic or heteroaromatic group. For example, Ar may be a C₆₋₃₀ aromatic organic group or a C₃₋₃₀ heteroaromatic organic group. For example, Ar may be a C₆₋₂₀ aromatic organic group or a C₃₋₂₀ heteroaromatic organic group.

X and Y are substituents that are directly attached to Ar. X may be hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group. Y may be OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which may optionally include —O—, —NR— (wherein R is hydrogen or C₁₋₁₀ alkyl group), —C(═O)—, or a combination thereof. R₆ and R₇ may be optionally connected to form a ring, and R₈ and R₉ may be optionally connected to form a ring. L is a single bond or divalent linking group. The linking group may be a C₁₋₃₀ linking group, an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination of at least two of the foregoing. The C₁₋₃₀ linking group may include a heteroatom containing O, S, N, F, or a combination of at least one of the foregoing heteroatoms. In an embodiment, the linking group may be —C(R¹⁰)₂—, —N(R¹¹)—, —O—, —S—, —S(═O)₂—, —(C═O)—, or a combination thereof, wherein each R³⁰ and R³¹ is independently hydrogen or a C₁₋₆ alkyl group. Preferably, X is hydrogen or a substituted or unsubstituted C₁₋₅ alkyl group, Y is OR₄ optionally including —O—, —C(═O)—, or a combination thereof, and L is a single bond. Variables m and n are each independently 1, 2, 3, 4, 5, 6, 7, 8, 9, 10, 11, 12, 13, 14, 15, 16, 17, 18, 19, or 20, provided that a sum of m and n does not exceed the total number of atoms of Ar available for substitution with X and Y. R₁ to R₃ may each independently be hydrogen, a substituted or unsubstituted C₁₋₁₀ alkyl group, a substituted or unsubstituted C₂₋₁₀ alkenyl group, a substituted or unsubstituted C₂₋₁₀ alkynyl group, or a substituted or unsubstituted C₃₋₁₀ cycloalkyl group. Preferably, R₁ and R₂ are hydrogen and R₃ is hydrogen or a C₁₋₅ alkyl group.

The additive polymer may include a structural unit represented by Formula (II):

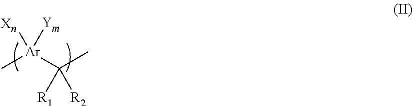

In Formula (II), Ar may be a C₆₋₄₀ aromatic organic group or a C₃₋₄₀ heteroaromatic organic group, each of which may be a single aromatic or heteroaromatic group or a fused aromatic or heteroaromatic group. For example, Ar may be a C₆₋₃₀ aromatic organic group or a C₃₋₃₀ heteroaromatic organic group. For example, Ar may be a C₆₋₂₀ aromatic organic group or a C₃₋₂₀ heteroaromatic organic group.

X and Y are substituents that are directly attached to Ar. X may be hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group. Y may be OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which may optionally include —O—, —NR— (wherein R is hydrogen or C₁₋₁₀ alkyl group), —C(═O)—, or a combination thereof. R₆ and R₇ may be optionally connected to form a ring, and R₈ and R₉ may be optionally connected to form a ring. Preferably, X is hydrogen or a substituted or unsubstituted C₁₋₅ alkyl group, and Y is OR₄ optionally including —O—, —C(═O)—, or a combination thereof. Variables m and n are each independently 1, 2, 3, 4, 5, 6, 7, 8, 9, 10, 11, 12, 13, 14, 15, 16, 17, 18, 19, or 20, provided that a sum of m and n does not exceed the total number of atoms of Ar available for substitution with X and Y. R₁ and R₂ may each independently be hydrogen, a substituted or unsubstituted C₁₋₁₀ alkyl group, a substituted or unsubstituted C₂₋₁₀ alkenyl group, a substituted or unsubstituted C₂₋₁₀ alkynyl group, or a substituted or unsubstituted C₃₋₁₀ cycloalkyl group. Preferably, R₁ and R₂ are hydrogen.

The additive polymer may include a structural unit represented by Formula (III):

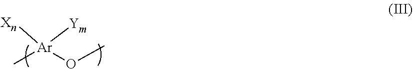

In Formula (III), Ar may be a C₆₋₄₀ aromatic organic group or a C₃₋₄₀ heteroaromatic organic group, each of which may be a single aromatic or heteroaromatic group or a fused aromatic or heteroaromatic group. For example, Ar may be a C₆₋₃₀ aromatic organic group or a C₃₋₃₀ heteroaromatic organic group. For example, Ar may be a C₆₋₂₀ aromatic organic group or a C₃₋₂₀ heteroaromatic organic group.

In Formula (III), X and Y are substituents that are directly attached to Ar. X may be hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group. Y may be OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which may optionally include —O—, —NR— (wherein R is hydrogen or C₁₋₁₀ alkyl group), —C(═O)—, or a combination thereof. R₆ and R₇ may be optionally connected to form a ring, and R₈ and R₉ may be optionally connected to form a ring. Preferably, X is hydrogen or a substituted or unsubstituted C₁₋₅ alkyl group, and Y is OR₄ optionally including —O—, —C(═O)—, or a combination thereof. Variables m and n are each independently 1, 2, 3, 4, 5, 6, 7, 8, 9, 10, 11, 12, 13, 14, 15, 16, 17, 18, 19, or 20, provided that a sum of m and n does not exceed the total number of atoms of Ar available for substitution with X and Y.

In some embodiments, the additive polymer may include each of a structural unit represented by Formula (I), Formula (II), and Formula (III).

The amount of the structural unit represented by Formula (I), a structural unit represented by Formula (II), a structural unit represented by Formula (III), or a combination thereof in the additive polymer may be 1 mol % to 100 mol % based on the total amount of all repeating units in the additive polymer. For example, the amount of the structural unit represented by Formula (I), a structural unit represented by Formula (II), a structural unit represented by Formula (III), or a combination thereof in the additive polymer may be 30 mol % to 100 mol %, 40 mol % to 100 mol %, 50 mol % to 100 mol %, 60 mol % to 100 mol %, 70 mol % to 100 mol %, 80 mol % to 100 mol %, or 90 mol % to 100 mol % based on the total amount of all repeating units in the additive polymer. In an embodiment, the amount of the structural unit represented by Formula (I), a structural unit represented by Formula (II), a structural unit represented by Formula (III), or a combination thereof in the additive polymer may be 50 mol % to 100 mol % based on the total amount of all repeating units in the additive polymer.

Examples of the additive polymers are listed below.

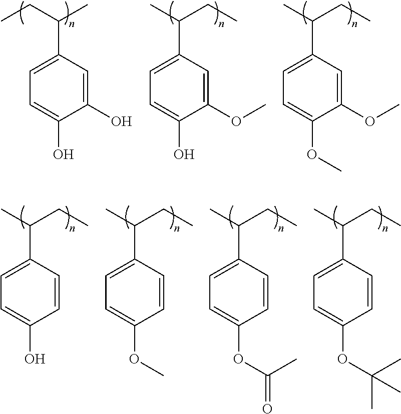

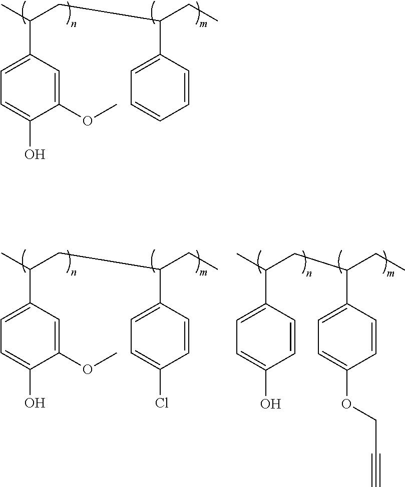

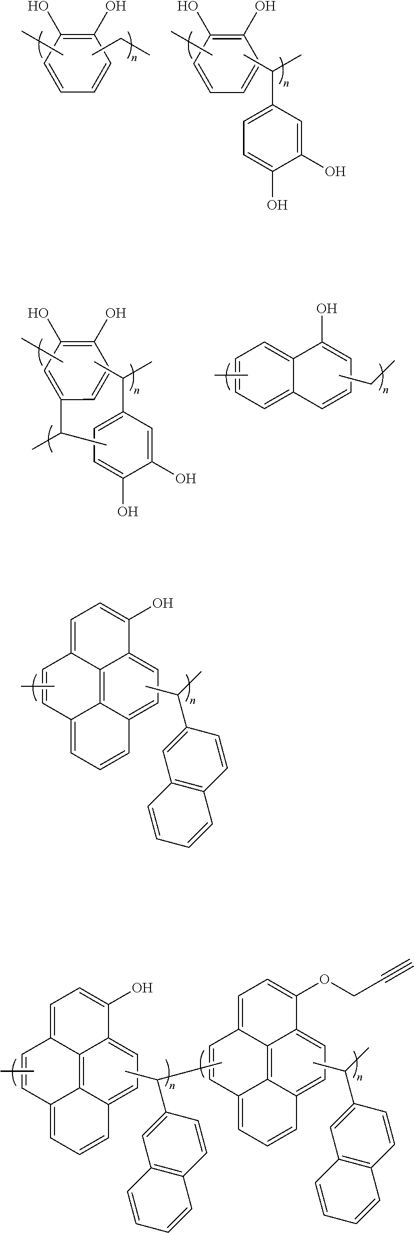

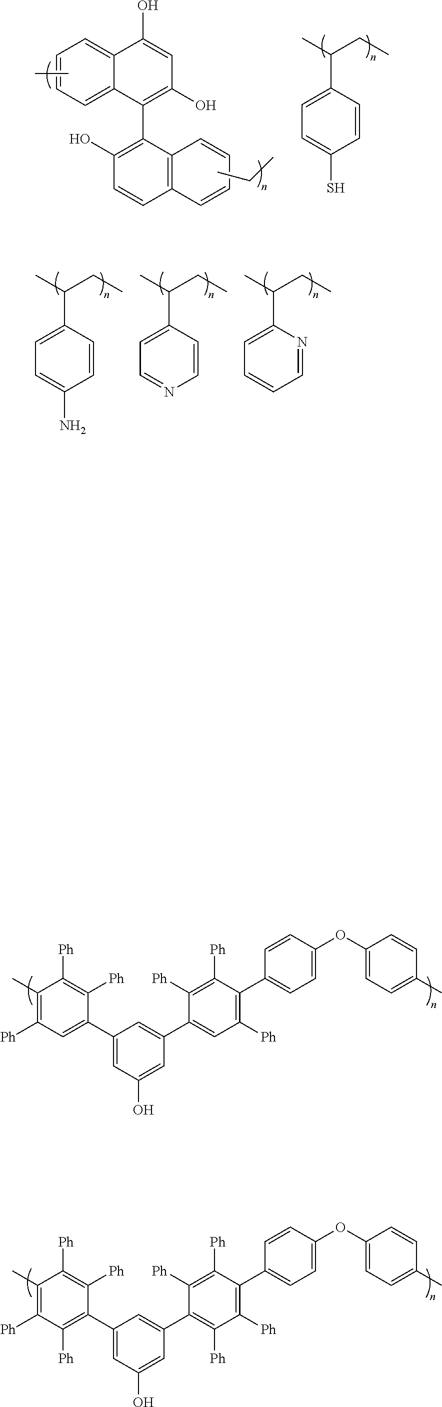

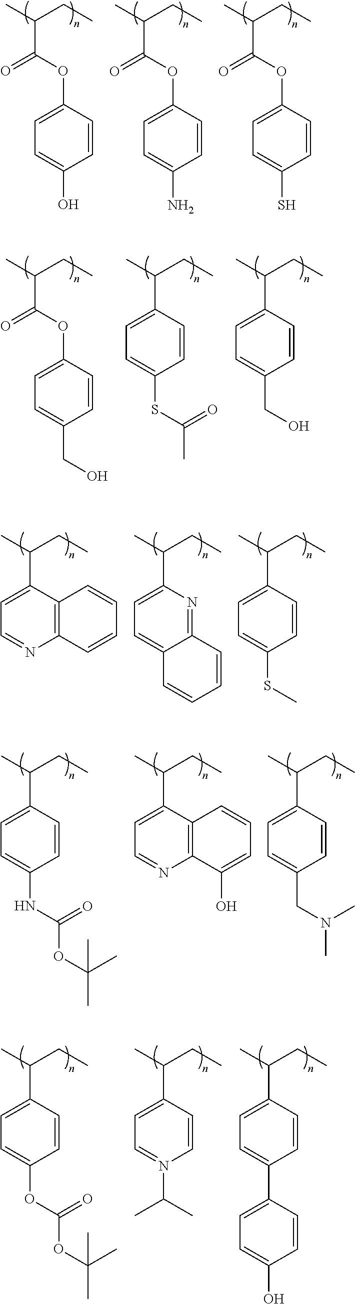

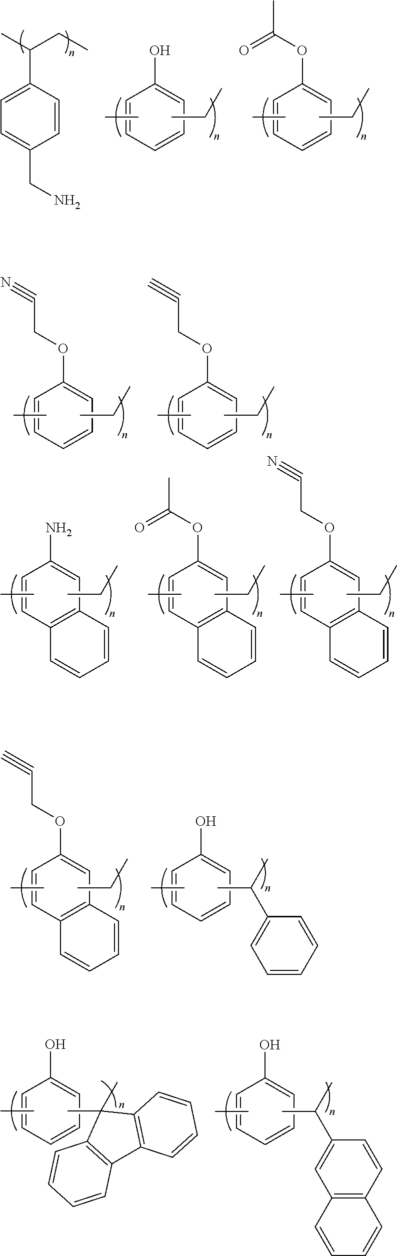

The additive polymers, according to an embodiment, have a weight average molecular weight (M_{W}) of 1,000-1,000,000 Da, preferably from 2,000-100,000 Da, more preferably from 2,000-20,000 Da. The additive polymers, according to an embodiment, typically have a number average molecular weight (Mₙ) in the range of 1,000-10,000 Da. The present additive polymers have a polydispersity index (PDI) of 1-3, preferably from 1.5-2.5. PDI=M_{W}/Mₙ. The Mₙ and M_{W} of the present polymers are determined by the conventional technique of gel permeation chromatography (GPC) against polystyrene standards using uninhibited tetrahydrofuran (THF) as eluting solvent at 1 mL/min and a differential refractometer detector. The present additive polymers have a degree of polymerization (DP) in the range of from 10-10,000, preferably from 20-1,000, more preferably from 20-200. DP is calculated by dividing the molecular weight of the polymer by the molecular weight of the respective repeating unit, exclusive of any end capping monomer present. Particularly preferred additive polymers, according to an embodiment, are those having a M_{W} of 2,000-20,000, a PDI of 1.5-2.5, and a ratio of total moles of first monomer to total moles of all monomers of from 50%-100%.

The resist underlayer composition may further include a solvent. A solvent may an organic solvent typically used in the electronics industry, such as propylene glycol methyl ether (PGME), propylene glycol methyl ether acetate (PGMEA), methyl 3-methoxypropionate (MMP), ethyl lactate, n-butyl acetate, anisole, N-methyl pyrrolidone, gamma-butyrolactone, ethoxybenzene, benzyl propionate, benzyl benzoate, propylene carbonate, xylene, mesitylene, cumene, limonene, and mixtures thereof. Mixtures of organic solvents are may be used, such as a mixture including one or more of anisole, ethoxybenzene, PGME, PGMEA, GBL, MMP, n-butyl acetate, benzyl propionate and benzyl benzoate in combination with one or more additional organic solvents, and more preferably a mixture comprising two or more of anisole, ethoxybenzene, PGME, PGMEA, GBL, MMP, n-butyl acetate, benzyl propionate, xylene, mesitylene, cumene, limonene, and benzyl benzoate. When a mixture of solvents is used, the ratio of solvents is generally not critical and may vary from 99:1 to 1:99 weight-to-weight (w/w), provided that the solvent mixture is able to dissolve the components of the composition. It will be appreciated by those skilled in the art that the concentration of the components in the organic solvent may be adjusted by removing a portion of the organic solvent or by adding more of the organic solvent, as may be desired.

The amount of the additive polymer in the composition may be 0.1 to 30 weight percent (weight %) based on the total weight of solids in the composition. For example, the amount of the additive polymer in the composition may be 0.1 to 25 weight %, 0.1 to 20 weight %, 0.1 to 15 weight %, or 0.1 to 10 weight % based on the total weight of solids in the composition. In another example, the amount of the additive polymer in the composition may be 0.5 to 30 weight %, 0.5 to 25 weight %, 0.5 to 20 weight %, 0.5 to 15 weight %, or 0.5 to 10 weight % based on the total weight of solids in the composition. In still another example, the amount of the additive polymer in the composition may be 1 to 30 weight %, 1 to 25 weight %, 1 to 20 weight %, 1 to 15 weight %, or 1 to 10 weight % based on the total weight of solids in the composition. In yet another example, the amount of the additive polymer in the composition may be 5 to 30 weight %, 5 to 25 weight %, 5 to 20 weight %, 5 to 15 weight %, or 5 to 10 weight % based on the total weight of solids in the composition. It will be appreciated by those skilled in the art that the mount of the additive polymer in the composition may be adjusted to achieve desired adhesion of the resist underlayer composition to the substrate.

The resist underlayer composition may include optional additives, such as curing agents, cross-linking agents, surface leveling agents, or any combination thereof. The selection of such optional additives and their amounts are well within the ability of those skilled in the art. Curing agents are typically present in an amount of from 0 to 20 weight % based on total solids, and preferably from 0 to 3 weight %. Cross-linking agents are typically used in an amount of from 0 to 30 weight % based on total solids, and preferably from 3 to 10 weight %. Surface leveling agents are typically used in an amount of from 0 to 5 weight % based on total solids, and preferably from 0 to 1 weight %. The selection of such optional additives and their amounts used are within the ability of those skilled in the art.

Curing agents may optionally be used in the resist underlayer composition to aid in the curing of the deposited aromatic resin film. A curing agent is any component which causes curing of the polymer on the surface of a substrate. Preferred curing agents are acids, photoacid generators and thermal acid generators. Suitable acids include, but are not limited to: arylsulfonic acids such as p-toluenesulfonic acid; alkyl sulfonic acids such as methanesulfonic acid, ethanesulfonic acid, and propanesulfonic acid; perfluoroalkylsulfonic acids such as trifluoromethanesulfonic acid; and perfluoroarylsulfonic acids. A photoacid generator is any compound which liberates acid upon exposure to light. A thermal acid generator is any compound which liberates acid upon exposure to heat. Thermal acid generators are well-known in the art and are generally commercially available. See U.S. Pat. No. 6,261,743 (which is incorporated herein in its entirety by reference) for a discussion of use of a photoacid generator. Thermal acid generators are well-known in the art and are generally commercially available, such as from King Industries, Norwalk, Conn. Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators.

Examples of cross-linking agents may be amine-based crosslinkers such as melamine materials, including melamine resins such as manufactured by Cytec Industries and sold under the tradename of Cymel 300, 301, 303, 350, 370, 380, 1116 and 1130; glycolurils including those glycolurils available from Cytec Industries; and benzoquanamines and urea-based materials including resins such as the benzoquanamine resins available from Cytec Industries under the name Cymel 1123 and 1125, and urea resins available from Cytec Industries under the names of Powderlink 1174 and 1196. In addition to being commercially available, such amine-based resins may be prepared, for example, by the reaction of acrylamide or methacrylamide copolymers with formaldehyde in an alcohol-containing solution, or alternatively by the copolymerization of N-alkoxymethyl acrylamide or methacrylamide with other suitable monomers. Examples of cross-linking agents may be epoxy resins such as Bisphenol A epoxy resin, Bisphenol F epoxy resin, novolac epoxy resin, cycloaliphatic epoxy resin, and glycidylamine epoxy resin.

The resist underlayer composition may optionally include one or more surface leveling agents (or surfactants). While any suitable surfactant may be used, such surfactants are typically non-ionic. Exemplary non-ionic surfactants are those containing an alkyleneoxy linkage, such as ethyleneoxy, propyleneoxy, or a combination of ethyleneoxy and propyleneoxy linkages.

Also provided is a coated substrate, including (a) a substrate; (b) a resist underlayer formed from the resist underlayer composition over the substrate; and (c) a photoresist layer over the resist underlayer. The coated substrate may further include a silicon-containing layer and/or an organic antireflective coating layer disposed above the resist underlayer and below the photoresist layer.

The described above compositions can be used to deposit the polyarylene ether coating on a patterned semiconductor device substrate, where the polyarylene ether coating layer has a suitable thickness, such as from 10 nm to 500 m, preferably from 25 nm to 250 m, and more preferably from 50 nm to 125 m, although such coatings may be thicker or thinner than these ranges depending on the particular application. The present compositions substantially fill, preferably fill, and more preferably fully fill, a plurality of gaps on a patterned semiconductor device substrate. An advantage of the present polyarylene ethers is that they planarize (form planar layers over a patterned substrate) and fill the gaps with substantially no voids being formed, and preferably without forming voids.

Preferably, after being coated on the patterned semiconductor device substrate surface, the resist underlayer composition is heated (soft baked) to remove any organic solvent present. Typical baking temperatures are from 80 to 170° C., although other suitable temperatures may be used. Such baking to remove residual solvent is typically done for approximately 30 seconds to 10 minutes, although longer or shorter times may suitably be used. Following solvent removal, a layer, film or coating of the resist underlayer on the substrate surface is obtained. Preferably, the resist underlayer is next cured to form a film. Such curing is typically achieved by heating, such as heating to a temperature of ≥300° C., preferably ≥350° C., and more preferably ≥400° C. Such curing step may take from 1 to 180 minutes, preferably from 10 to 120 minutes, and more preferably from 15 to 60 minutes, although other suitable times may be used. Such curing step may be performed in an oxygen-containing atmosphere or in an inert atmosphere, and preferably in an inert atmosphere.

Optionally, an organic antireflectant layer may be disposed directly on the resist underlayer. Any suitable organic antireflectant may be used. As used herein, the term “antireflectant” refers to a moiety or a material that absorbs actinic radiation at the wavelength of use. Suitable organic antireflectants are those sold under the AR™ brand by Dow Electronic Materials. The particular antireflectant used will depend on the particular photoresist used, the manufacturing process used, and on other considerations well within the ability of those skilled in the art. In use, the organic antireflectant is typically spin-coated onto the surface of the resist underlayer, followed by heating (soft baking) to remove any residual solvent and then curing to form an organic antireflectant layer. Such soft baking and curing steps may be performed in a single step.

A photoresist layer may then be deposited on the resist underlayer, such as by spin-coating. In a preferred embodiment, the photoresist layer is deposited directly on the resist underlayer (called a tri-layer process). In an alternate preferred embodiment, the photoresist layer is deposited directly on the organic antireflectant layer (called a quad-layer process). A wide variety of photoresists may be suitably used, such as those used in 193 nm lithography, such as those sold under the Epic™ brand available from Dow Electronic Materials (Marlborough, Mass.). Suitable photoresists may be either positive tone development or negative tone development resists.

Optionally, one or more barrier layers may be disposed on the photoresist layer. Suitable barrier layers include a topcoat layer, a top antireflectant coating layer (or TARC layer), and the like. Preferably, a topcoat layer is used when the photoresist is patterned using immersion lithography. Such topcoats are well-known in the art and are generally commercially available, such as OC™ 2000 available from Dow Electronic Materials. It will be appreciated by those skilled in the art that a TARC layer is not needed when an organic antireflectant layer is used under the photoresist layer.

Following coating, the photoresist layer is then imaged (exposed) using patterned actinic radiation, and the exposed photoresist layer is then developed using the appropriate developer to provide a patterned photoresist layer. The photoresist is preferably patterned using an immersion lithography process, which is well-known to those skilled in the art. The pattern is next transferred from the photoresist layer to the underlayers by an appropriate etching techniques known in the art, such as by plasma etching, resulting in a patterned resist underlayer in a tri-layer process and a patterned organic antireflectant layer in a quad-layer process. If a quad-layer process is used, the pattern is next transferred from the organic antireflectant layer to the resist underlayer using appropriate pattern transfer techniques, such as plasma etching. The resist underlayer is then patterned using appropriate etching techniques, such as O₂ or CF₄ plasma. Any remaining patterned photoresist and organic antireflectant layers are removed during pattern transfer etching of the resist underlayer. Next, the pattern is transferred to a layer below the resist underlayer, such as by appropriate etching techniques, such as by plasma etching and/or wet chemical etching, to provide a patterned semiconductor device substrate. For example, the pattern may be transferred to the semiconductor device substrate. Resist underlayers of the invention preferably withstand wet chemical etch processes during pattern transfer to one or more layers below the resist underlayer. Suitable wet chemical etch chemistries include, for example, mixtures comprising ammonium hydroxide, hydrogen peroxide, and water (e.g., SC-1 clean); mixtures comprising hydrochloric acid, hydrogen peroxide, and water (e.g., SC-2 clean); mixtures comprising sulfuric acid, hydrogen peroxide, and water; mixtures comprising phosphoric acid, hydrogen peroxide, and water; mixtures comprising hydrofluoric acid and water; mixtures comprising hydrofluoric acid, phosphoric acid, and water; mixtures comprising hydrofluoric acid, nitric acid, and water; mixtures comprising tetramethylammonium hydroxide and water; and the like. The patterned semiconductor device substrate is then processed according to conventional means. As used herein, the term “underlayer” refers to all removable processing layers between the semiconductor device substrate and the photoresist layer, namely the optional organic antireflectant layer and the resist underlayer.

The resist underlayer, according to an embodiment, may also be used in a self-aligned double patterning process. In such a process, a layer of an underlayer resist composition described above is coated on a substrate, such as by spin-coating. Any remaining organic solvent is removed and the coating layer is cured to form a resist underlayer. A suitable middle layer, such as a silicon-containing hardmask layer is optionally coated on the resist underlayer. A layer of a suitable photoresist is then coated on the middle layer, such as by spin coating. The photoresist layer is then imaged (exposed) using patterned actinic radiation, and the exposed photoresist layer is then developed using the appropriate developer to provide a patterned photoresist layer. The pattern is next transferred from the photoresist layer to the middle layer and the resist underlayer by appropriate etching techniques to expose portions of the substrate. Typically, the photoresist is also removed during such etching step. Next, a conformal silicon-containing layer is disposed over the patterned resist underlayer and exposed portions of the substrate. Such silicon-containing layer is typically an inorganic silicon layer such as SiON or SiO₂ which is conventionally deposited by CVD. Such conformal coatings result in a silicon-containing layer on the exposed portions of the substrate surface as well as over the underlayer pattern, that is, such silicon-containing layer substantially covers the sides and top of the underlayer pattern. Next, the silicon-containing layer is partially etched (trimmed) to expose a top surface of the patterned resist underlayer and a portion of the substrate. Following this partial etching step, the pattern on the substrate comprises a plurality of features, each feature comprising a line or post of the resist underlayer with the silicon-containing layer directly adjacent to the sides of each resist underlayer feature. Next, exposed regions of the resist underlayer are removed, such as by etching, to expose the substrate surface that was under the resist underlayer pattern, and providing a patterned silicon-containing layer on the substrate surface, where such patterned silicon-containing layer is doubled (that is, twice as many lines and/or posts) as compared to the patterned resist underlayer.

Films formed from preferred resist underlayer compositions of the invention show excellent thermal stability, as measured by weight loss, as compared to conventional polyarylene polymers or oligomers prepared from the Diels-Alder reaction of biscyclopentadienone monomers and polyalkyne-substituted aromatic monomers. Cured films formed from the present polymers have ≤4% weight loss after heating at 450° C. for 1 hour, and preferably <4% weight loss. Such cured films also have a decomposition temperature of >480° C. as determined by 5% weight loss, and preferably >490° C. Higher decomposition temperatures are desired to accommodate higher processing temperatures use in the manufacture of semiconductor devices. Without wishing to be bound by any particular theory, it is believed that addition of additive polymers as adhesion promoters into the formulations described herein can improve adhesion of the polyarylene ethers to substrates by either entangling with the polyarylene ether or by providing an adhesive interlayer between the polyarylene ether and the substrate. Preferred resist underlayers of the invention can, as a result, withstand wet chemical etch processes and chemistries such as described above.

The present inventive concept is further illustrated by the following examples. All compounds and reagents used herein are available commercially except where a procedure is provided below.

### EXAMPLES

Matrix Polymer Synthesis:

### Example 1. Polyarylene Ether (1)

A mixture of 30.0 g of 3,3′-(oxydi-1,4-phenylene)bis(2,4,5-triphenylcyclopentadienone) (DPO-CPD), 18.1 g 1,3,5-tris(phenylethynyl)benzene (TRIS) and 102.2 g of GBL was heated at 185° C. for 14 hours. The reaction was then allowed to cool to room temperature and diluted with 21.5 g of GBL. The crude reaction mixture was added to 1.7 L of a 1:1 mixture of iso-propyl alcohol (IPA)/PGME and stirred for 30 minutes. The solid was collected by vacuum filtration and washed with 1:1 mixture of IPA/PGME. To the solid was added 0.4 L of water and the slurry was heated to 50° C. and stirred at 50° C. for 30 minutes. The warm slurry was filtered by vacuum filtration. The wet cake was vacuum dried for 2 days at 70° C. providing 34.1 g of Oligomer 1 in 71% yield. Analysis of Oligomer 1 provided a M_{W} of 3487 Da and a PDI of 1.42.

### Example 2. Polyarylene Ether (2)

Oligomer 1 (10 g) from Example 1 was charged to a 100 mL single neck round bottom flask equipped with a reflux condenser, thermocouple and nitrogen atmosphere; followed by GBL (20 g). The reaction was stirred and warmed to 145° C., at which point phenyl acetylene (1 g) was added as an end-capping monomer. The reaction was kept at 145° C. for a total of 12 hours, at which point the reaction became clear. The end-capped oligomer was isolated by precipitating the reaction mixture into an excess (200 g) of methyl tert-butyl ether (MTBE) to yield 7 g of Oligomer 2.

The above procedures were used for matrix polymers 3-4 and additive polymer 5.

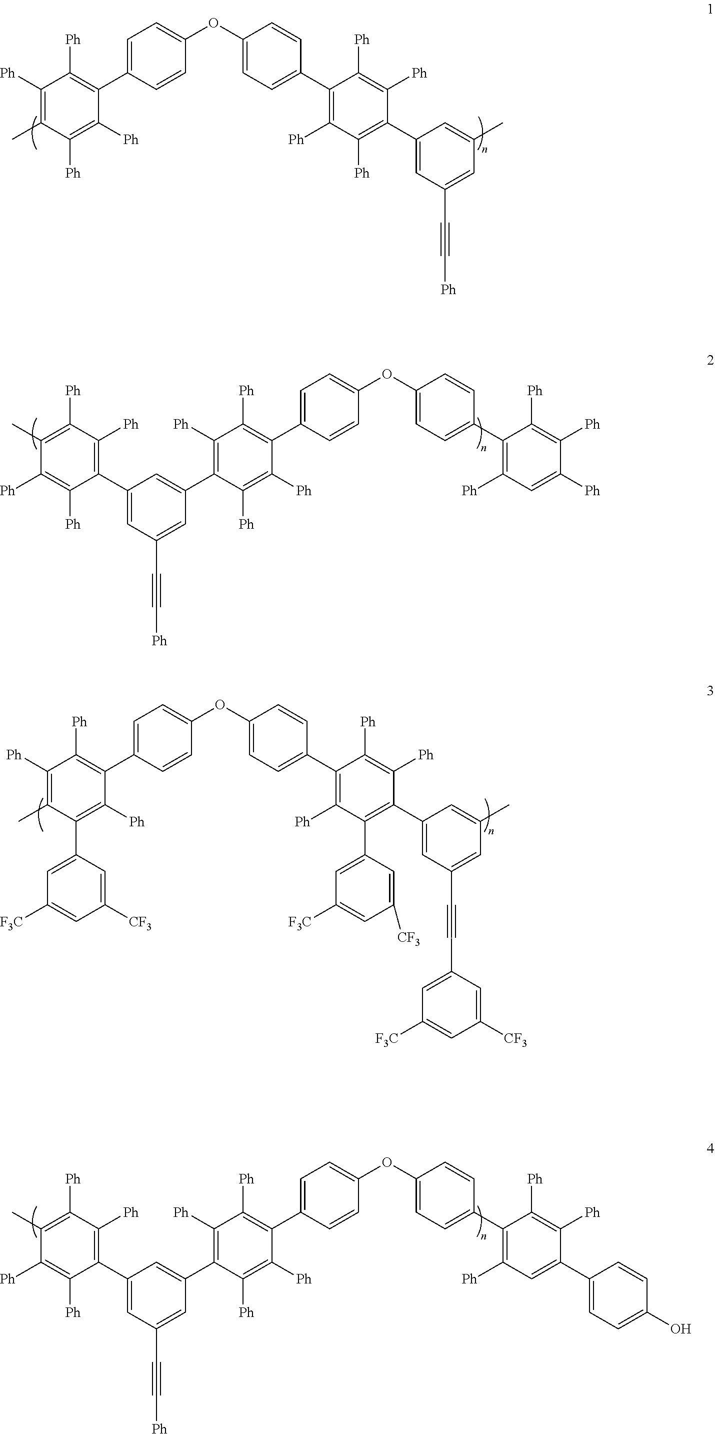

### Additive Polymer Synthesis

### Example 3. Poly(methoxystyrene) (11)

4-Methoxystyrene (70 g) was dissolved in PGMEA (138 g) and V-601 initiator (5.88 g) was added. The resulting mixture was heated to 90° C. under a nitrogen blanket, and the heating was continued overnight. After the reaction was complete, the mixture was cooled to room temperature and precipitated into 1.5 L of a 4:1 volume-to-volume (v/v) mixture of methanol and water to give a white solid. The precipitated polymer was collected by vacuum filtration and dried in a vacuum oven for 24 hours to afford additive polymer poly(methoxystyrene) as a white solid (˜60 g). M_{W} was determined by GPC relative to polystyrene standard and was found to be 8,735 Da (PDI 2.2).

### Example 4. Poly(acetoxystyrene) (10)

4-Acetoxystyrene (45.2 g) was dissolved in PGMEA (91.7 g) and V-601 initiator (3.2 g) was added. The resulting mixture was heated to 90° C. under a nitrogen blanket, and the heating was continued overnight. After the reaction was complete, the mixture was cooled to room temperature and precipitated into 1.5 L of a 1:1 (v/v) mixture of methanol and water to give a white solid. The precipitated polymer was collected by vacuum filtration and dried in a vacuum oven for 24 hours to afford additive polymer poly(acetoxystyrene) as a white solid (42.5 g). M_{W} was determined by GPC relative to polystyrene standard and was found to be 11,703 Da (PDI 2.2).

The generic procedure above was used for additive polymers 6-15 and 24.

### Example 5: 1,1′-Bi-2-naphthol Novolac (22)

1,1′-Bi-2-naphthol (10.0 g) and paraformaldehyde (1.05 g) were mixed in 25 mL PGME and warmed to 60° C. with stirring. Then, methanesulfonic acid (0.34 g) was added slowly, and the reaction was heated to 120° C. for 16 hours. After this time, the mixture was cooled to room temperature and precipitated directly into a stirring mixture of 700 mL methanol/30 mL water. The solid was collected by filtration and dried in a vacuum oven overnight to give a brown solid (8.6 g). M_{W} was determined by GPC relative to polystyrene standard and was found to be 4,335 Da (PDI 3.4).

The above procedure was used for additive polymers 16-21.

### Example 6. Poly(glycidyl methacrylate) (23)

Glycidyl methacrylate (10 g) was dissolved in PGMEA (23.3 g) and V-601 initiator (0.89 g) was added. The resulting mixture was heated to 80° C. under a nitrogen blanket, and the heating was continued overnight. After the reaction was complete, the mixture was cooled to room temperature and precipitated into 600 mL of a 4:1 volume-to-volume (v/v) mixture of methanol and water to give a white solid. The precipitated polymer was collected by vacuum filtration and dried in a vacuum oven for 24 hours to afford additive polymer poly(glycidyl methacrylate) as a white solid (˜9 g).

The above procedure was used for additive polymer 25.

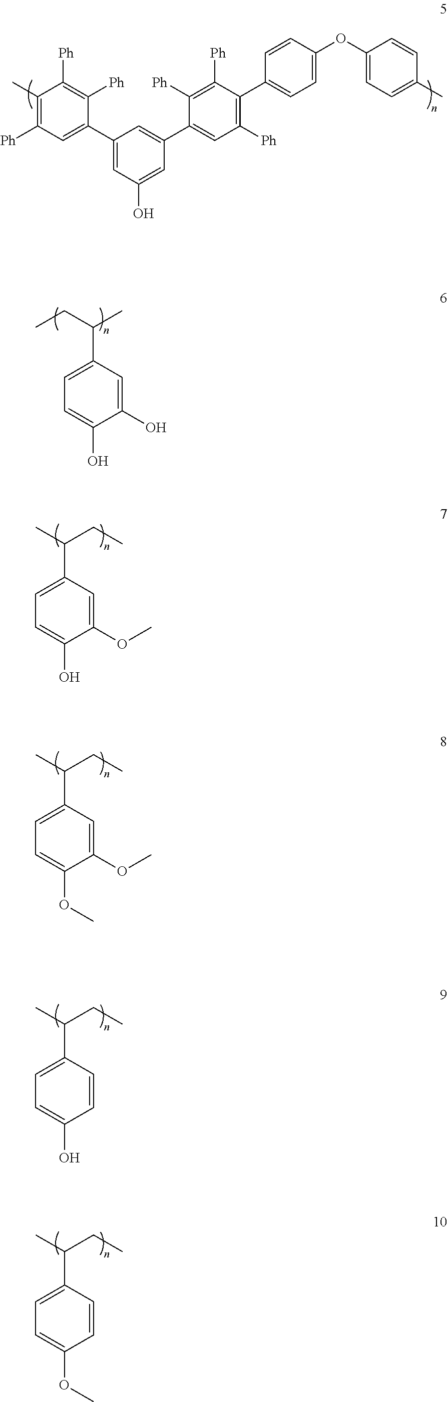

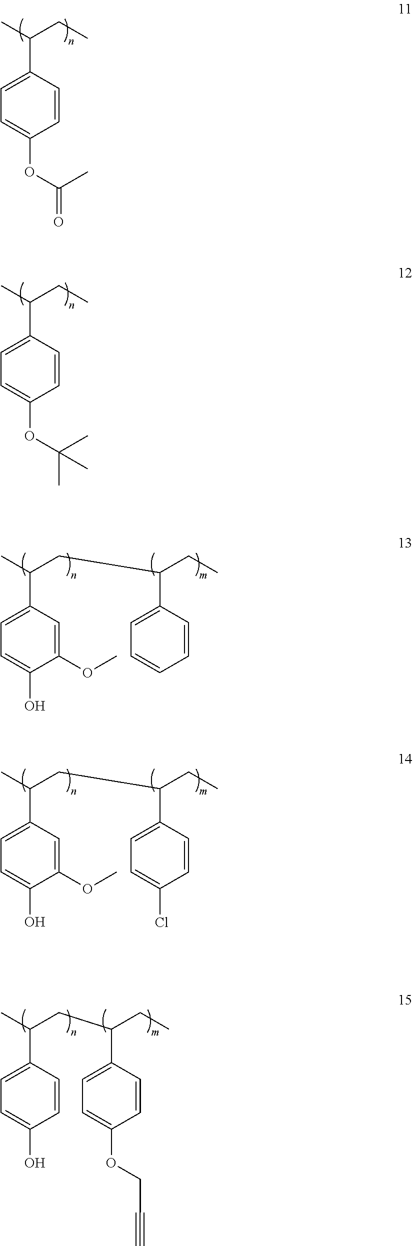

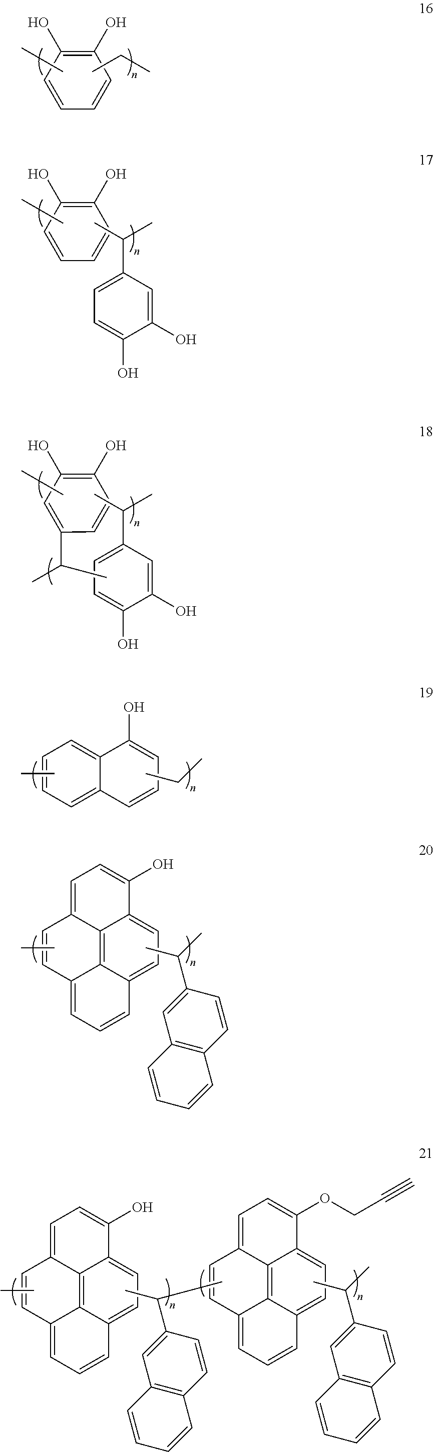

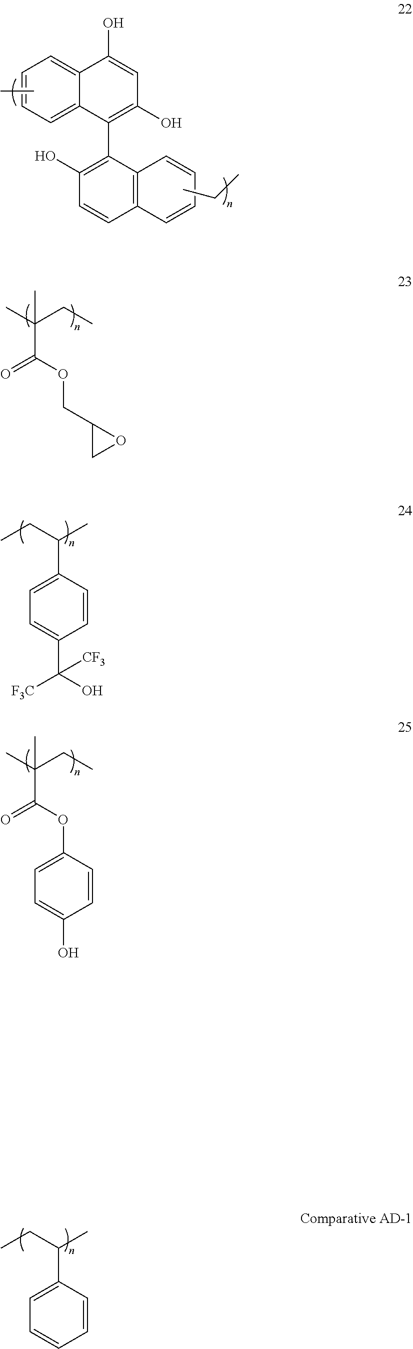

### Evaluation Examples

Formulations with Additive

The formulations were prepared by dissolving a polymer and one or more adhesion promoting additives in a mixture of PGMEA and benzyl benzoate (97:3) at approximately 4 weight % solids. The amount of the additive relative to the total solid was listed in the table. The obtained solutions were filtered through a 0.2 m poly(tetrafluoroethylene) (PTFE) syringe filter.

### Formulations Without Additive

The formulations were prepared by dissolving a polymer in a mixture of PGMEA and benzyl benzoate (97:3) at approximately 4 weight % solids. The obtained solutions were filtered through a 0.2 m poly(tetrafluoroethylene) (PTFE) syringe filter.

### Standard Coating and Cleaning

Standard coating process of the above formulations was performed on both TiN and Si substrates. The coating process includes spin coating, soft baking at 170° C. for 60 s, and hard bake at 450° C. for 4 minutes.

Standard cleaning solution (SC1) was prepared by mixing 30% ammonium hydroxide, 30% hydrogen peroxide, and deionized water at a ratio of 1:5:40 (w/w). Both ammonium hydroxide and hydrogen peroxide were purchased from Fisher Scientific and used as received. Wafer coupons coated with various films were immersed into a bath containing the standard cleaning solution at 70° C. with a gentle agitation. The treated coupons were rinsed with deionized water twice and air dried. The time before significant film delamination (visual observation) were recorded to evaluate the resistance of the SOC coating to stripping by the standard cleaning solution. SOC coated Si wafers were clipped to coupon size and prepared by the same method. Crosshatch markers were made by scribing pens to simulate patterns. Film thickness was measured before and after the treatment with the standard cleaning solution on the non-delaminated area to verified minimal film thickness changes.

### Film Shrinkage Measurement

Film shrinkage amount was calculated as FT reduction after soft bake to after hard bake divided by initial FT after soft bake according to Equation 1.

$$Shrinkage = \frac{{FT}_{SB} - {FT}_{HB}}{{FT}_{SB}} \cdot 100 \% \qquad Equation 1$$

Standard cleaning delamination time on TiN substrate for SOC formulations with adhesion promoting polymeric additives in comparison to comparative example are listed in Table 1.

TABLE 1

| | | | | Standard |
|---|---|---|---|---|
| | | | Additive % | cleaning |
| Experiment | Matrix | | in overall | resistance |
| No. | Polymer | Additive | solid | time (min) |
| 1-1 | 1 | 6 | 2 | 10 |
| 1-2 | 1 | 20 | 2 | 3 |
| 1-3 | 1 | 22 | 2 | 2 |
| 1-4 | 1 | 16 | 2 | 16 |
| 1-5 | 1 | 9 | 2 | 5 |
| 1-6 | 1 | 9 | 0.5 | 4 |
| 1-7 | 1 | 15 | 2 | 5 |
| 1-8 | 1 | 15 | 3 | 3 |
| 1-9 | 1 | 7 | 2 | 18 |
| 1-10 | 1 | 13 | 2 | 13 |
| 1-11 | 1 | 21 | 2 | 5 |
| 1-12 | 1 | 17 | 1 | 6 |
| 1-13 | 1 | 18 | 1 | 9 |
| 1-14 | 1 | 10 | 1 | 4 |
| 1-15 | 1 | 8 | 1 | 7 |
| 1-16 | 1 | 11 | 3 | 11 |
| 1-17 | 1 | 12 | 3 | 6 |
| 1-18 | 1 | 9 | 1 | 4 |
| | | 23 | 1 | |
| 1-19 | 1 | 14 | 10 | 12 |
| 1-20 | 1 | 5 | 16 | 3 |
| 1-21 | 1 | 25 | 3 | 4 |
| Comp. 1-1 | 1 | | 0 | 1 |
| Comp. 1-2 | — | AD-1 | 2 | 1 |

Standard cleaning delamination time on Si substrate for SOC formulations with adhesion promoting polymeric additives in comparison to comparative example are listed in Table 2.

TABLE 2

| | | | | Standard |
|---|---|---|---|---|
| | | | | cleaning |
| Experiment | Matrix | | additive % | resistance |
| No. | Polymer | Additive | in solid | time (min) |
| 2-1 | 1 | 20 | 2 | 7 |
| 2-2 | 1 | 6 | 1 | 17 |
| 2-3 | 1 | 22 | 2 | 12 |
| 2-4 | 1 | 16 | 2 | 8 |
| 2-5 | 1 | 19 | 1 | 11 |
| 2-6 | 1 | 7 | 2 | 21 |
| 2-7 | 1 | 13 | 2 | 9 |
| 2-8 | 1 | 21 | 2 | 5 |
| 2-9 | 1 | 9 | 2 | 20 |
| 2-10 | 1 | 9 | 0.5 | 7 |
| 2-11 | 1 | 15 | 2 | 26 |
| 2-12 | 1 | 15 | 3 | 12 |
| 2-13 | 1 | 10 | 1 | 5 |
| 2-14 | 1 | 8 | 1 | 11 |
| 2-15 | 1 | 11 | 3 | 11 |
| 2-16 | 1 | 12 | 3 | 7 |
| 2-17 | 1 | 9 | 1 | 5 |
| | | 23 | 1 | |
| 2-18 | 1 | 14 | 10 | 10 |
| 2-19 | 1 | 5 | 16 | 6 |
| 2-20 | 1 | 24 | 5 | 6 |
| Comp. 2-1 | 1 | — | 0 | 4 |

Standard cleaning delamination time on TiN and Si substrate for modified polyphenylene formulations with and without adhesion promoting polymeric additives are listed in Table 3.

TABLE 3

| | | | | Standard | Standard |
|---|---|---|---|---|---|
| | | | | cleaning | cleaning |
| | | | | resistance | resistance |
| Experiment | Matrix | Addi- | Additive % | time | time |
| No. | Polymer | tive | in solid | (TiN, min) | (Si, min) |
| Comp 3-1 | 2 | — | — | 3 | 2 |
| 3-1 | 2 | 9 | 2 | 11 | >20 |
| 3-2 | 2 | 10 | 1 | 5 | 2 |
| Comp 3-2 | 3 | — | — | 2 | 2 |
| 3-3 | 3 | 9 | 2 | 8 | 3 |
| Comp 3-3 | 4 | — | — | 5 | 7 |
| 3-4 | 4 | 9 | 2 | 4 | 11 |

Film thickness shrinkage for adhesion improved formulation after hard bake compared to additives and matrix polymers.

TABLE 4

| | | | | Shrinkage |
|---|---|---|---|---|
| | | | | before |
| Experiment | Matrix | | additive % | and after |
| No. | polymer | Additive | in solid | 450° C./4 min |
| 4-1 | 1 | — | 0 | <3% |
| 4-2 | 1 | 9 | 2 | |
| 4-3 | 1 | 11 | 3 | |
| 4-4 | 1 | 12 | 3 | |
| 4-5 | 1 | 10 | 1 | |
| 4-6 | 2 | — | 0 | <6% |
| 4-7 | 2 | 10 | 1 | |
| 4-8 | 3 | — | 0 | |
| 4-9 | 3 | 9 | 2 | |
| 4-10 | — | 9 | 100% | 100% |
| 4-11 | — | 11 | 100% | |
| 4-12 | — | 10 | 100% | |
| 4-13 | — | 8 | 100% | |

Thermal degradation temperatures for adhesion improved formulation compared to additives and matrix polymer are listed in Table 5.

TABLE 5

| Experiment | | |
|---|---|---|
| No. | Polymer | Td 5 weight % loss temperature |
| 5-1 | 20 | <350° C. |
| 5-2 | 6 | |
| 5-3 | 11 | |
| 5-4 | 9 | |
| 5-5 | 8 | |
| 5-6 | 21 | |
| 5-7 | 9 | |
| 5-8 | 16 | |
| 5-9 | 15 | |
| 5-10 | 12 | |
| 5-11 | 1 | >450° C. |
| 5-12 | 2 | |
| 5-13 | 3 | |
| 5-14 | 4 | |

Table 5 shows that adhesion additives are not thermally stable at 450° C., and that matrix polymers are stable at that temperature. The film coated by an additive itself completely degraded away during the 450° C. hard bake. The formulation with added adhesion promotor surprisingly shows improved adhesion even though additive would presumably degrade away during hard bake at 450° C.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A resist underlayer composition, comprising:
a polyarylene ether,
an additive polymer that is different from the polyarylene ether, and
a solvent,
wherein the additive polymer comprises an aromatic or heteroaromatic group,
wherein the aromatic group comprises at least one protected or free functional group selected from hydroxy, thiol, and amino.

2. The resist underlayer composition of claim 1, wherein the at least one protected or free functional group is hydroxy.

3. The resist underlayer composition of claim 1 or 2, wherein the at least one functional group is protected with a protecting group optionally comprising —O—, —NR— (wherein R is hydrogen or C₁₋₁₀alkyl group), —C(═O)—, or a combination thereof.

4. The resist underlayer composition of claim 3, wherein the protecting group comprises a formyl group, a substituted or unsubstituted linear or branched C₁₋₁₀ alkyl group, a substituted or unsubstituted C₃₋₁₀ cycloalkyl group, a substituted or unsubstituted C₂₋₁₀ alkenyl group, a substituted or unsubstituted C₂₋₁₀ alkynyl group, or a combination thereof, wherein the protecting group optionally comprises —O—, —NR— (wherein R is hydrogen or C₁₋₁₀ alkyl group), —C(═O)—, or a combination thereof.

5. The resist underlayer composition of any one of claims 1 to 4, wherein the additive polymer comprises a structural unit represented by Formula (I): 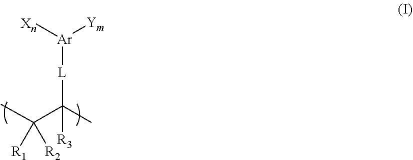
wherein, in Formula (I),
Ar is a C₆₋₄₀ aromatic organic group or a C₃₋₄₀ heteroaromatic organic group;
X and R₁ to R₃ are each independently hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group;
Y is OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which optionally comprises —O—, —NR— (wherein R is hydrogen or C₁₋₁₀ alkyl group), —C(═O)—, or a combination thereof, wherein R₆ and R₇ are optionally connected to form a ring, and wherein R₈ and R₉ are optionally connected to form a ring;
L is a single bond or a divalent linking group; and
m and n are each independently an integer from 1 to 20, provided that a sum of m and n does not exceed the total number of atoms of Ar available for substitution with X and Y.

6. The resist underlayer composition of any one of claims 1 to 4, wherein the additive polymer comprises a structural unit represented by Formula (II): 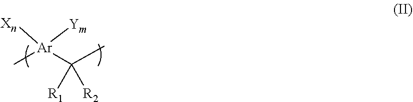
wherein, in Formula (II),
Ar is a C₆₋₄₀ aromatic organic group or a C₃₋₄₀ heteroaromatic organic group;
X, R₁, and R₂ are each independently hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group;
Y is OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which optionally comprises —O—, —NR— (wherein R is hydrogen or C₁₋₁₀ alkyl group), —C(═O)—, or a combination thereof, wherein R₆ and R₇ are optionally connected to form a ring, and wherein R₈ and R₉ are optionally connected to form a ring; and
m and n are each independently an integer from 1 to 20, provided that a sum of m and n does not exceed the total number of atoms of Ar available for substitution with X and Y.

7. The resist underlayer composition of any one of claims 1 to 4, wherein the additive polymer comprises a structural unit represented by Formula (III): 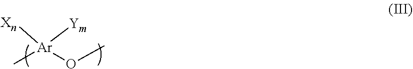
wherein, in Formula (III),
Ar is a C₆₋₄₀ aromatic organic group or a C₃₋₄₀ heteroaromatic organic group;
X is hydrogen, a substituted or unsubstituted C₁₋₁₀ alkyl group, a substituted or unsubstituted C₂₋₁₀ alkenyl group, a substituted or unsubstituted C₂₋₁₀ alkynyl group, a substituted or unsubstituted C₃₋₁₀ cycloalkyl group, or a substituted or unsubstituted C₆₋₂₀ aryl group;
Y is OR₄, SR₅, NR₆R₇, or CR₈R₉OR₄, wherein R₄ to R₉ are each independently hydrogen, a formyl group, a substituted or unsubstituted C₁₋₅ alkyl group, a substituted or unsubstituted C₂₋₅ alkenyl group, a substituted or unsubstituted C₂₋₅ alkynyl group, or a substituted or unsubstituted C₃₋₈ cycloalkyl group, each of which optionally comprises —O—, —NR— (wherein R is hydrogen or C₁₋₁₀ alkyl group), —C(═O)—, or a combination thereof, wherein R₆ and R₇ are optionally connected to form a ring, and wherein R₈ and R₉ are optionally connected to form a ring; and
m and n are each independently an integer from 1 to 20, provided that a sum of m and n does not exceed the total number of atoms of Ar available for substitution with X and Y.

8. The resist underlayer composition of any one of claims 1 to 7, wherein an amount of the additive polymer is 0.1 to 20 weight percent based on the total weight of solids in the composition.

9. A method of forming a pattern, the method comprising: (a) applying a layer of the resist underlayer composition of any one of claims 1 to 8 over a substrate; (b) curing the applied resist underlayer composition to form a resist underlayer; and (c) forming a photoresist layer over the resist underlayer.

10. The method of claim 9, further comprising forming a silicon-containing layer and/or an organic antireflective coating layer above the resist underlayer prior to forming the photoresist layer.

11. The method of claim 9 or 10, further comprising patterning the photoresist layer and transferring the pattern from the patterned photoresist layer to the resist underlayer and to a layer below the resist underlayer.

12. The method of claim 11, wherein transferring the pattern comprises a wet chemical etch process.
